(19) United States
(12) Patent Application Publication
(10) Pub. No.: US 2018/0012861 A1
(43) Pub. Date: Jan. 11, 2018

(54) METHOD OF MANUFACTURING ELECTRONIC APPARATUS

(71) Applicant: Electronics and Telecommunications Research Institute, Daejeon (KR)

(72) Inventors: Ji-Young OH, Daejeon (KR); Joo Yeon KIM, Daejeon (KR); Jae Bon KOO, Daejeon (KR); Bock Soon NA, Daejeon (KR); Nae-Man PARK, Daejeon (KR); Chan Woo PARK, Daejeon (KR); Sang Seok LEE, Sejong-si (KR); Soon Won JUNG, Daejeon (KR); Chi-Sun HWANG, Daejeon (KR); Keunsoo LEE, Daejeon (KR)

(73) Assignee: Electronics and Telecommunications Research Institute, Daejeon (KR)

(21) Appl. No.: 15/631,678

(22) Filed: Jun. 23, 2017

(30) Foreign Application Priority Data
Jul. 7, 2016 (KR) 10-2016-0086286

(51) Int. Cl. H01L 23/00

(52) U.S. Cl. CPC H01L 24/83; H01L 2224/8349; H01L 2924/078

(57) ABSTRACT

Provided is a method of manufacturing an electronic apparatus which includes preparing a substrate having a first Young's modulus, disposing a thin film having a second Young's modulus greater than the first Young's modulus on the substrate, disposing an electronic device on the thin film, and disposing a capping layer configured to cover the electronic device on the thin film.

### CROSS-REFERENCE TO RELATED APPLICATIONS

This U.S. non-provisional patent application claims priority under 35 U.S.C. §119 of Korean Patent Application No. 10-2016-0086286, filed on Jul. 7, 2016, the entire contents of which are hereby incorporated by reference.

### STATEMENT REGARDING PRIOR DISCLOSURES BY THE INVENTOR OR A JOINT INVENTOR

Applicant hereby states under 37 CFR 1.77(b)(6) that Ji-Young Oh, Joo Yeon Kim, Chan Woo Park, Soon Won Jung, Bock Soon Na, Keunsoo Lee, Nae-Man Park, Sang Seok Lee, Jae Bon Koo and Chi-Sun Hwang, “Spontaneously Formed Wrinkled Substrates for Stretchable Electronics Using Intrinsically Rigid Materials,” IEEE Electron Device Letters, Mar. 29, 2016, is designated as a grace period inventor disclosure. The disclosure: (1) was made one year or less before the effective filing date of the claimed invention; (2) names the inventor or a joint inventor as an author; and (3) does not name additional persons as authors on a printed publication.

### BACKGROUND OF THE INVENTION

The present disclosure herein relates to methods of manufacturing an electronic apparatus, and more particularly, to methods of manufacturing an electronic apparatus having stretchability.

Research into stretchable electronic devices has been actively conducted due to wearable devices. Since application of stretchable electric devices using brittle, rigid metal or semiconductor material itself is impossible, research, in which a stretchable device is fabricated by preparing metal wiring and semiconductor thin film in a wavy shape or bulky shape and transferring the metal wiring and semiconductor thin film to a stretchable substrate, has been conducted to overcome this limitation. However, since the process is complex, there is a limitation in realizing a large-area electronic device.

In order to address the limitation, a fabrication method has been studied in which an electronic device is fabricated on a thin substrate having a sacrificial layer and an entire thin film including the electronic device is then transferred to a stretchable substrate, but a process of transferring the thin film layer having a thickness of about 15 μm or less may be very complex.

Also, since the stretchable substrate has a Young's modulus that is about 1,000 times lower than that of the semiconductor material and has a high coefficient of thermal expansion (CTE>>10 ppm ° C.), mechanical exfoliation and cracks may occur at an interface between thin films (metal, insulation layer, etc.) constituting the substrate and the device to cause difficulties in direct fabrication of an electronic device on the stretchable substrate.

Thus, there is a need to develop a stretchable composite substrate, which enables a stretchable device to be manufactured by a general device manufacturing process without using a complex process in which a thin film is used or transferred, and a method of manufacturing the stretchable composite substrate.

### SUMMARY OF THE INVENTION

The present disclosure provides a method of more easily and simply manufacturing a stretchable electronic apparatus.

The object of the present invention is not limited to the aforesaid, but other objects not described herein will be clearly understood by those skilled in the art from descriptions below.

An embodiment of the inventive concept provides a method of manufacturing an electronic apparatus including preparing a substrate having a first Young's modulus; disposing a thin film having a second Young's modulus greater than the first Young's modulus on the substrate; disposing an electronic device on the thin film; and disposing a capping layer configured to cover the electronic device on the thin film.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a flowchart illustrating a method of manufacturing an electronic apparatus according to an embodiment of the inventive concept;

FIG. 2 is a cross-sectional view illustrating an electronic apparatus according to an embodiment of the inventive concept;

FIGS. 3 to 5 are images of surfaces of films of Experimental Examples 1 to 3 which are observed with a microscope;

FIGS. 6 and 7 are images of surfaces of films of Experimental Examples 4 and 5 which are observed with a microscope;

FIG. 8 is an image of the surface of the film of Experimental Example 4 which is observed by using an atomic force microscope (AFM);

FIG. 9 is a graph in which stretchability is evaluated by depositing an electrode on the film of Experimental Example 5;

FIGS. 10 and 11 are graphs in which stretchability of an electronic apparatus including the film of Experimental Example 5 is evaluated; and

FIG. 12 is an image of a pentacene thin film transistor including the film of Experimental Example 5 which is observed with a microscope.

### DETAILED DESCRIPTION OF PREFERRED EMBODIMENTS

The foregoing and other objects, features and advantages of the present disclosure will become more readily apparent from the following detailed description of preferred embodiments of the present disclosure that proceeds with reference to the appending drawings. The present disclosure may, however, be embodied in different forms and should not be construed as limited to the embodiments set forth herein. Rather, these embodiments are provided so that this disclosure will be thorough and complete, and will fully convey the scope of the inventive concept to those skilled in the art.

In this specification, it will be understood that when an element is referred to as being “on” another element, it can be directly on the other element or intervening elements may also be present therebetween. Also, in the figures, the thicknesses of elements are exaggerated for clarity of illustration.

The embodiments in the detailed description will be described with sectional and/or plan views as ideal exemplary views of the inventive concept. In the figures, the thicknesses of layers and regions are exaggerated for clarity of illustration. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a device region. Thus, this should not be construed as limited to the scope of the inventive concept. It will be understood that, although the terms first, second, etc. may be used herein to describe various elements, these elements should not be limited by these terms. These terms are only used to distinguish one element from another element. Embodiments described and exemplified herein include complementary embodiments thereof.

In the following description, the technical terms are used only for explaining a specific exemplary embodiment while not limiting the inventive concept. The terms of a singular form may include plural forms unless referred to the contrary. It will be understood that the terms “comprises” and/or “comprising”, when used in this specification, specify the presence of stated elements, but do not preclude the presence or addition of one or more other elements.

Hereinafter, embodiments of the inventive concept will be described in detail with reference to the accompanying drawings.

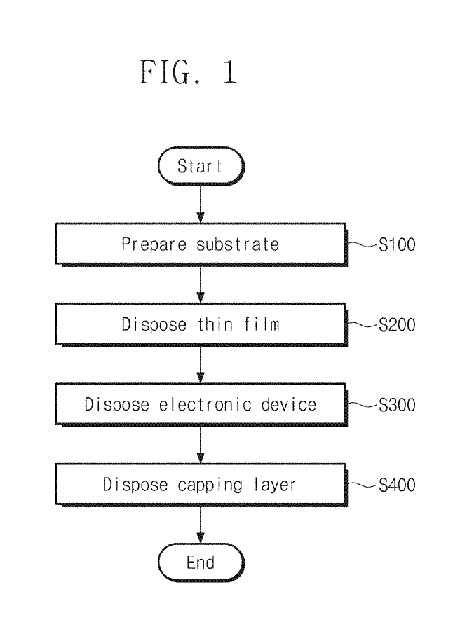

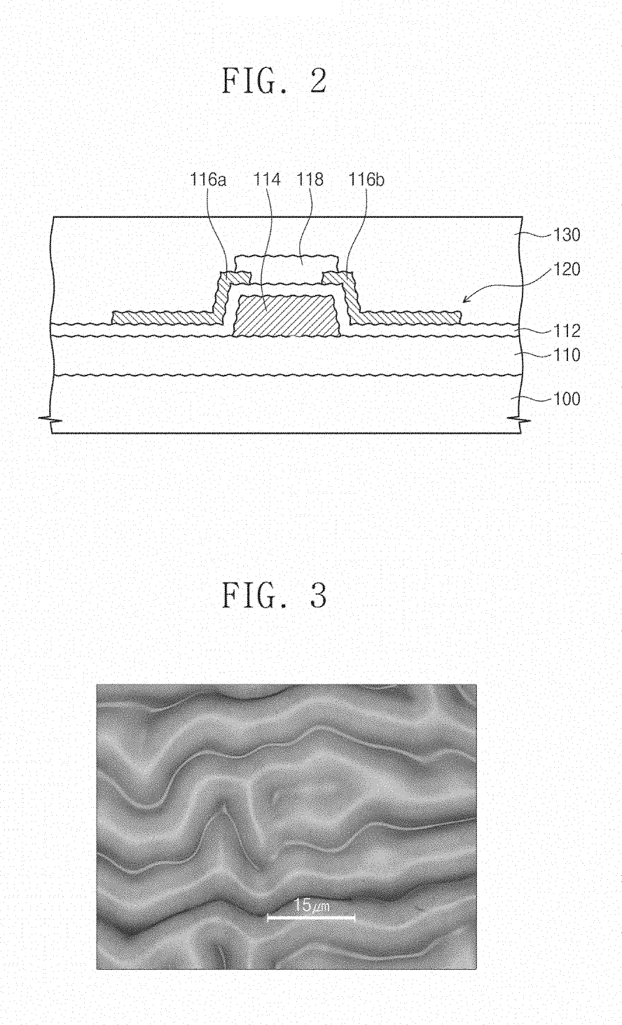

FIG. 1 is a flowchart illustrating a method of manufacturing an electronic apparatus according to an embodiment of the inventive concept, and FIG. 2 is a cross-sectional view illustrating an electronic apparatus according to an embodiment of the inventive concept.

Referring to FIGS. 1 and 2, a substrate 100 is provided (step S100). According to an embodiment of the inventive concept, the substrate 100 may have a Young's modulus of less than about 0.1 GPa. For example, the substrate 100 may include at least one selected from the group consisting of polydimethylsiloxane (PDMS), ecoflex, and polyurethane.

According to an embodiment of the inventive concept, the substrate 100 may be formed by mixing a hardener with at least one of polymers, such as PDMS, ecoflex, and polyurethane, and curing the mixture. A thickness of the substrate 100 formed may be in a range of about 0.01 mm to about 10 mm. In this case, the Young's modulus of the substrate 100 may be controlled by adjusting a ratio of the polymer to the hardener.

A top surface of the substrate 100 is in a state in which a wavy structure to be described later is not formed. That is, the top surface of the substrate 100 may be a flat surface.

A thin film 110 may be disposed on the substrate 100 (step S200). According to an embodiment of the inventive concept, the thin film 110 may have a Young's modulus greater than the Young's modulus of the substrate 100. The thin film 110 may have a Young's modulus of about 0.1 GPa to about 5.0 GPa. For example, the thin film 110 may include at least one selected from the group consisting of parylene, poly(vinyl chloride) (PVC), and poly(methyl methacrylate) (PMMA). According to an embodiment of the inventive concept, the thin film 110 may be formed by coating on the substrate 100 to a thickness of about 10 nm to about 20 μm and then curing the coating.

During the curing of the thin film 110, wrinkles may be formed on the thin film 110 by a difference in Young's modulus at an interface between the substrate 100 and the thin film 110. Specifically, when the Young's modulus of the substrate 100 is less than about 0.1 GPa and the Young's modulus of the thin film 110 is in a range of about 0.1 GPa to about 5.0 GPa, the substrate 100 may be relatively more elastic in tensile or compression than the thin film 110. During the curing of the thin film 110 after the two layers having different Young's moduli, i.e., the substrate 100 and the thin film 110, are bonded, the thin film 110 may have a wavy structure. Protrusions and recesses may be irregularly formed on the thin film 110. On a plane, a plurality of wrinkles may be irregularly formed on the thin film 110. A period and a width of the wrinkles of the thin film 110 may be controlled according to a type of each material of the substrate 100 and the thin film 110 and a thickness of each of the substrate 100 and the thin film 110 provided.

Also, since the substrate 100 includes a polymer, such as PDMS, ecoflex, and polyurethane, and the thin film 110 includes a polymer such as parylene, PVC, and PMMA, adhesion between the substrate 100 and the thin film 110 is excellent, and thus, a phenomenon may be suppressed in which the thin film 110 is exfoliated from the substrate 100 in a subsequent process.

An electronic device 120 may be disposed on the thin film 110 (step S300). In the present embodiment, although a pentacene thin film transistor is exemplarily described as the electronic device 120, the electronic device 120 of the inventive concept is not limited to the pentacene thin film transistor. The pentacene thin film transistor may include a gate electrode 114, a gate dielectric 112, source and drain electrodes 116a and 116b, and a pentacene active pattern 118.

The gate electrode 114, the gate dielectric 112, the source and drain electrodes 116a and 116b, and the pentacene active pattern 118 may have a wavy structure. Protrusions and recesses may be irregularly formed on the gate electrode 114, the gate dielectric 112, the source and drain electrodes 116a and 116b, and the pentacene active pattern 118. On a plane, a plurality of wrinkles may be irregularly formed on the gate electrode 114, the gate dielectric 112, the source and drain electrodes 116a and 116b, and the pentacene active pattern 118.

A capping layer 130 configured to cover the electronic device 120 may be disposed on the thin film 110 on which the electronic device 120 is disposed (step S400). The capping layer 130 may include at least one selected from the group consisting of PDMS, ecoflex, and polyurethane. For example, the capping layer 130 may be formed by mixing a hardener with at least one of polymers, such as PDMS, ecoflex, and polyurethane, and curing the mixture. In this case, a Young's modulus of the capping layer 130 may be controlled by adjusting a ratio of the polymer to the hardener.

Thus, since the thin film 110 having a low Young's modulus is disposed on the substrate 100 having a high Young's modulus, the thin film 110 may have wrinkles and the electronic device 120 may be directly disposed on the wavy thin film 110. Thus, an electronic apparatus may be more easily provided.

### Experimental Example 1

PDMS was mixed with a hardener in a ratio of about 10:0.5, and about 9.7 g of the mixture was then put in a square plastic container having a size of about 100 mm×about 100 mm and cured for about 2 hours in an oven at about 60° C. A thickness of the cured PDMS substrate was about 0.6 mm. Polyimide was coated on the PDMS substrate at about 2,000 rpm for about 30 seconds and then cured at about 150° C. for about 2 hours to obtain a film.

### Experimental Example 2

A film was obtained in the same manner as in Experimental Example 1 except that the ratio of the PDMS to the hardener was changed to about 10:1.0.

### Experimental Example 3

A film was obtained in the same manner as in Experimental Example 1 except that the ratio of the PDMS to the hardener was changed to about 10:3.0.

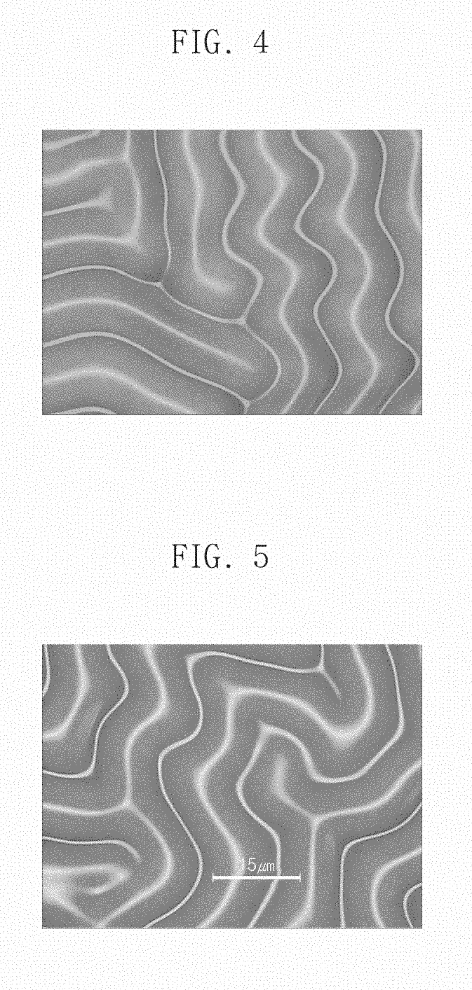

FIGS. 3 to 5 are images of surfaces of the films of Experimental Examples 1 to 3 which were observed with a microscope. Referring to FIGS. 3 to 5, it may be understood that a period and a width of wrinkles on the surfaces of the films were different depending on the ratio of the hardener.

### Experimental Example 4

PDMS was mixed with a hardener in a ratio of about 10:1, and about 9.7 g of the mixture was then put in a square plastic container having a size of about 100 mm×about 100 mm and cured for about 2 hours in an oven at about 60° C. A thickness of the cured PDMS substrate was about 0.6 mm Parylene was coated on the PDMS substrate to a thickness of about 400 nm and then cured to obtain a film.

### Experimental Example 5

A film was obtained in the same manner as in Experimental Example 4 except that parylene was coated on the PDMS substrate to a thickness of about 800 nm.

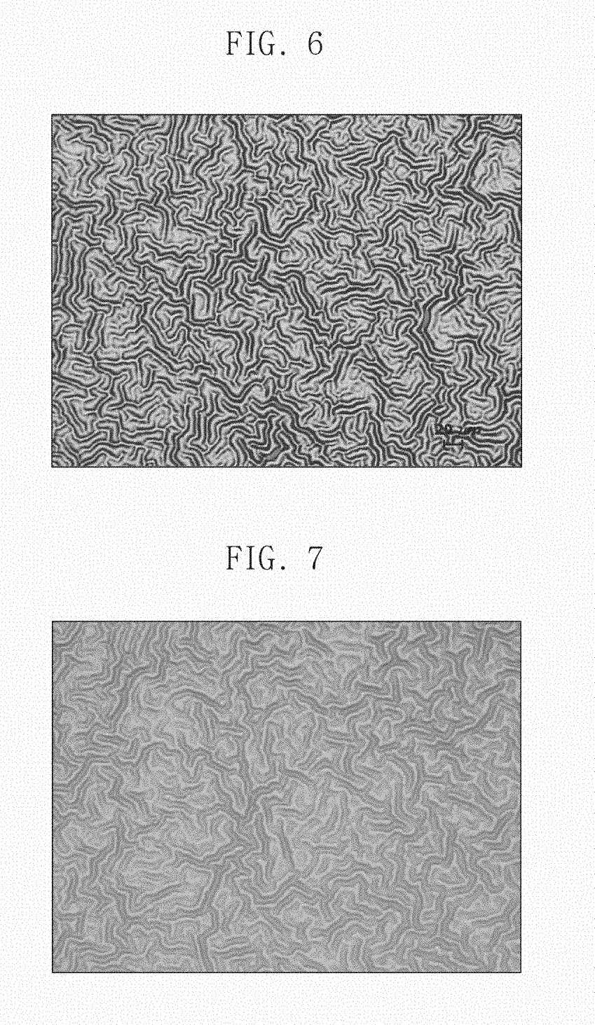

FIGS. 6 and 7 are images of surfaces of the films of Experimental Examples 4 and 5 which were observed with a microscope. Referring to FIGS. 6 and 7, it may be understood that a period and a width of wrinkles formed on each of the films were different depending on the thickness of the parylene coated on the PDMS substrate.

Also, when compared with FIGS. 3 to 5, it may be understood that the period and width of the wrinkles formed on each of the films were different depending on the material coated on the PDMS substrate.

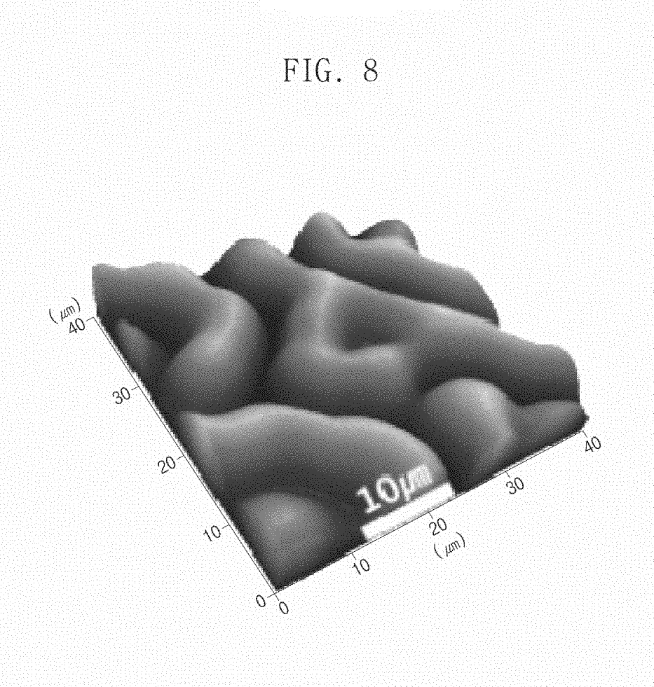

FIG. 8 is an image of the surface of the film of Experimental Example 4 which was observed by using an atomic force microscope (AFM). Referring to FIG. 8, it may be observed that the wrinkles of the film included protrusions and recesses and were irregular.

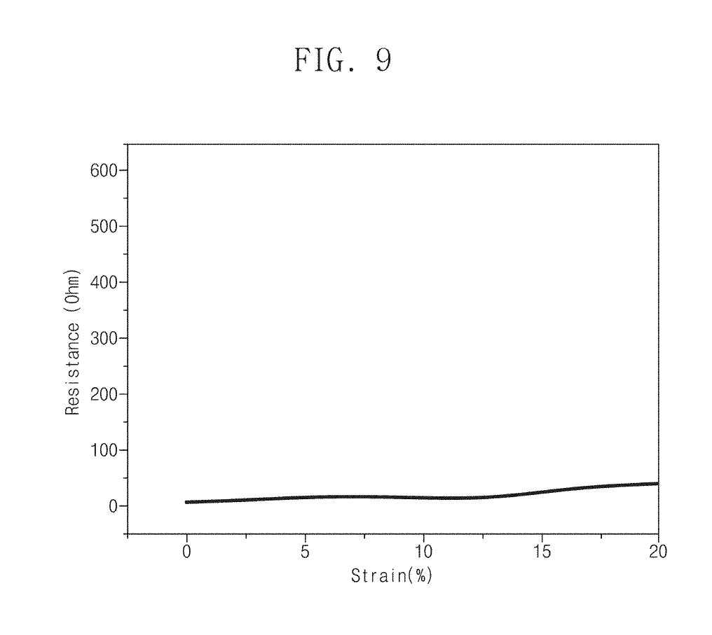

FIG. 9 is a graph in which stretchability was evaluated by depositing an interconnection on the film of Experimental Example 5. The stretchability was evaluated by depositing an about 70 nm thick gold (Au) interconnection having a width of about 3 mm and a length of about 11 mm on the film of Experimental Example 5. Referring to FIG. 9, it may be understood that resistance of the Au interconnection disposed on the film, which was coated with the parylene on the PDMS substrate to a thickness of about 800 nm, was not substantially changed even if strain was increased. Thus, it may be understood that the Au interconnection disposed on the film, which was coated with the parylene on the PDMS substrate to a thickness of about 800 nm, also had stretchability.

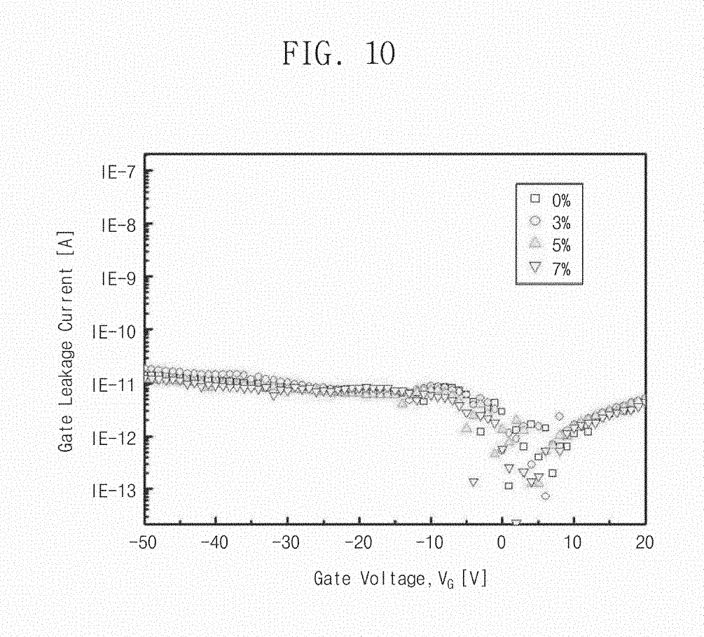

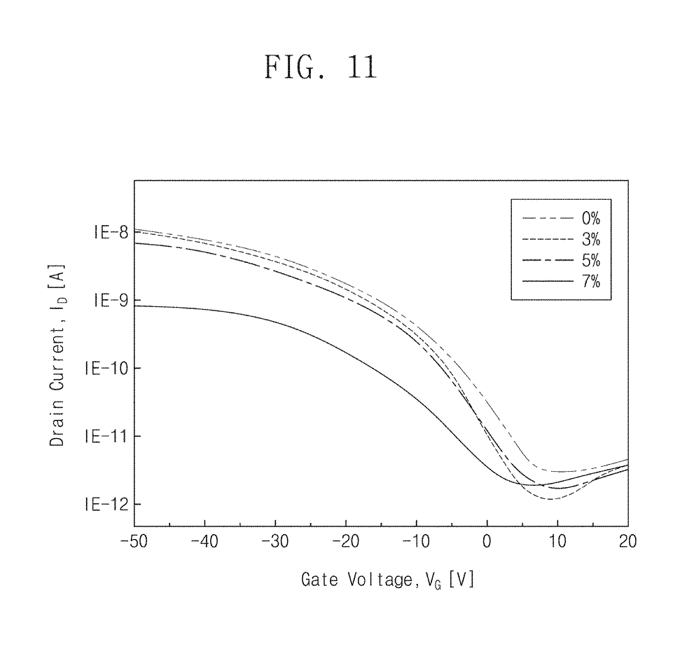

FIGS. 10 and 11 are graphs in which stretchability of an electronic apparatus including the film of Experimental Example 5 was evaluated. For the simplicity of the description, descriptions of substantially the same contents as those described with reference to FIG. 2 may not be provided.

Referring again to FIG. 2, an electronic apparatus for stretchability evaluation may be provided. For the evaluation of the stretchability, the gate electrode 114 including aluminum was formed on the films 100 and 110 of Experimental Example 5 to a thickness of about 70 nm and about 400 nm thick parylene was then deposited as the gate dielectric 112. As the source/drain electrodes 116a and 116b, Ti/Au was deposited with a thickness ratio of about 1 nm/70 nm. A width and a length of a channel were about 120 μm and about 40 μm, respectively. Subsequently, about 50 nm thick pentacene, as the semiconductor layer 118, was deposited to provide a pentacene thin film transistor. The capping layer 130 was formed on the pentacene thin film transistor by mixing PDMS and a hardener in a ratio of 10:1 and curing the mixture, and thus, an electronic apparatus was completed.

Referring to FIG. 10, the gate leakage current graphs, which were measured by varying the degree of stretching of the electronic apparatus, may be provided. Specifically, the electronic apparatus was stretched by about 0%, about 3%, about 5%, and about 7%. The four gate leakage current graphs according to the degree of stretching had similar values to one another. That is, it may be understood that gate leakage current characteristics were maintained even if the electronic apparatus of the inventive concept was stretched from about 0% to about 7%.

Referring to FIG. 11, the drain current graphs, which were measured by varying the degree of stretching of the electronic apparatus, may be provided. Specifically, the electronic apparatus was stretched by about 0%, about 3%, about 5%, and about 7%. It may be understood that drain currents of the electronic apparatus stretched by about 0%, the electronic apparatus stretched by about 3%, and the electronic apparatus stretched by about 5% were similar to one another. A drain current of the electronic apparatus stretched by about 7% was reduced by a maximum of about 0.1 times in comparison to the drain current of the electronic apparatus stretched by about 5%, but the electronic apparatus stretched by about 7% may perform a required operation. Thus, it may be understood that drain current characteristics were maintained even if the electronic apparatus of the inventive concept was stretched from about 0% to about 7%.

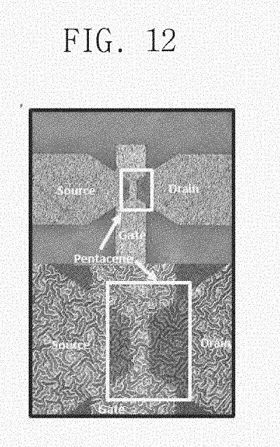

FIG. 12 is an image of the pentacene thin film transistor including the film of Experimental Example 5 which was observed with a microscope. For the simplicity of the description, descriptions of substantially the same contents as those described with reference to FIG. 2 may not be provided.

Referring to FIG. 12, it may be understood that a pentacene thin film transistor including source/drain electrodes, a gate electrode, and pentacene was provided on the film of Experimental Example 5. The expressions “Source”, “Drain”, “Gate”, and “Pentacene” may be the source electrode 116a, the drain electrode 116b, the gate electrode 114, and the pentacene active pattern 118 which have been described with reference to FIG. 2.

According to embodiments of the inventive concept, since a thin film having a Young's modulus greater than that of a substrate is formed on the substrate, stretchability due to the substrate may not only be obtained, but an electronic device may also be directly formed on the thin film. Thus, a process of forming a stretchable electronic apparatus may be facilitated and simplified.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed. Accordingly, it is to be understood that the inventive concept has been described by way of illustration and not limitation.

What is claimed is:

1. A method of manufacturing an electronic apparatus, the method comprising:
preparing a substrate having a first Young's modulus;
disposing a thin film having a second Young's modulus greater than the first Young's modulus on the substrate;
disposing an electronic device on the thin film; and
disposing a capping layer configured to cover the electronic device on the thin film.

2. The method of claim 1, wherein the first Young's modulus is less than 0.1 GPa.

3. The method of claim 1, wherein the second Young's modulus is in a range of 0.1 GPa to 5.0 GPa.

4. The method of claim 1, wherein the substrate is formed by mixing a hardener with one selected from the group consisting of polydimethylsiloxane (PDMS), ecoflex, and polyurethane, and curing the mixture.

5. The method of claim 1, wherein the thin film is formed by coating and curing one selected from the group consisting of parylene, poly(vinyl chloride) (PVC), and poly(methyl methacrylate) (PMMA) on the substrate.

6. The method of claim 1, wherein the capping layer comprises one selected from the group consisting of PDMS, ecoflex, and polyurethane.

7. The method of claim 1, wherein the substrate has a thickness of 0.01 mm to 10 mm.

8. The method of claim 1, wherein the thin film has a thickness of 10 nm to 20 μm.

9. The method of claim 1, wherein, during the disposition of the thin film, wrinkles are formed on the thin film by a difference in Young's modulus between the thin film and the substrate.
